(19) United States
(12) Patent Application Publication
(10) Pub. No.: US 2010/0281316 A1
(43) Pub. Date: Nov. 4, 2010

(54) SEMICONDUCTOR INTEGRATED CIRCUIT, INFORMATION PROCESSING APPARATUS, OUTPUT DATA DIFFUSION METHOD, AND PROGRAM

(76) Inventors: Yoshikazu MIYATO, Saitama (JP); Masafumi KUSAKAWA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/765,476

(22) Filed: Apr. 22, 2010

(30) Foreign Application Priority Data
May 1, 2009 (JP) P2009-111748

(51) Int. Cl. G01R 31/3177; G06F 11/25

(52) U.S. Cl. 714/726; 714/E11.155

(57) ABSTRACT

A semiconductor integrated circuit includes a scan chain configured to serve as a connection path used for testing the semiconductor integrated circuit and connect a plurality of flip-flops and an interleave circuit provided at an output portion of the scan chain. The interleave circuit includes a plurality of branches including different numbers of stages of storage elements, a selector configured to select one of the plurality of branches serving as an input/output branch that performs input of data from the scan chain and output of data from the interleave circuit, and a selector controller configured to execute a process of switching among the plurality of branches to select the input/output branch at every predetermined timing.

### BACKGROUND OF THE INVENTION

1. Field of the Invention

The present invention relates to a semiconductor integrated circuit, an information processing apparatus, an output data diffusion method, and a program. More specifically, the present invention relates to a semiconductor integrated circuit having a configuration for preventing leakage of information from a scan circuit, which is a test circuit for the semiconductor integrated circuit, an information processing apparatus, an output data diffusion method, and a program.

2. Description of the Related Art

Many flip-flops are used in a semiconductor integrated circuit. Flip-flops are each capable of holding a bit value (0 or 1) and performing input/output of a bit value at high speed, and are often used as elements constituting a cache memory, a register, or other electronic circuits. In this specification, the term flip-flop will be abbreviated as FF hereinafter.

According to the related art, a scan test is used as a method for testing a semiconductor integrated circuit. The configuration of a scan test described in Japanese Patent No. 3671948 will be described with reference to FIG. 1. As illustrated in FIG. 1, a semiconductor integrated circuit 100 includes combinational circuits 121 and 122, each composed of a plurality of circuit elements that execute various data processes and computation processes. Furthermore, the semiconductor integrated circuit 100 includes a plurality of FFs for holding and transferring data to be input to the combinational circuits 121 and 122 and data output from the combinational circuits 121 and 122. Specifically, scan FFs 111, 112, and 113 are provided as illustrated in FIG. 1.

Each of the scan FFs 111, 112, and 113 illustrated in FIG. 1 may include a plurality of scan FFs, instead of a single scan FF. A connection line for connecting the scan FFs 111, 112, and 113 illustrated in FIG. 1 is set as a scan chain for testing the circuit and is used for a test or the like in a manufacturing stage of the semiconductor integrated circuit.

A test is performed with the FFs before/after the combinational circuits being regarded as a data input unit and a data output unit for the combinational circuits. Data for the test is set in each FF, results of processes performed in the combinational circuits are stored in the FFs in the subsequent stage, and the results are taken to the outside, whereby it is determined whether the combinational circuits normally operate. A circuit test using the scan chain is called a scan test.

As illustrated in FIG. 1, a scan-in 131, a scan-clock (SCK) 132, a scan-enable 133, and a scan-out 134 are provided as external terminals of the semiconductor integrated circuit 100.

The scan-in 131 is a terminal for inputting values to be stored in the scan FFs during a scan test.

The SCK 132 is a terminal for inputting clock pulses that are used during a scan test, and the clock pulses are supplied to SCK input units of the respective scan FFs.

The scan-enable 133 is a terminal for switching input of the scan FFs, and a scan-enable (SE) signal is supplied therefrom to SE input units of the respective scan FFs.

The scan-out 134 is a terminal for outputting values stored in the scan FFs.

The combinational circuits 121 and 122 are sandwiched between the scan FFs 111, 112, and 113 illustrated in FIG. 1. In the scan test, a test is performed by executing input/output of data among the combinational circuits 121 and 122 and the scan FFs 111, 112, and 113.

An internal circuit configuration of each of the scan FFs 111, 112, and 113 will be described with reference to FIG. 2. Note that an FF that is connected to a scan chain and that is capable of selectively inputting test data and other data is called a scan FF. The internal circuit of each of the scan FFs 111, 112, and 113 has the configuration illustrated in FIG. 2. Although the configuration of only the scan FF 111 is illustrated in FIG. 2, the scan FFs 112 and 113 have the same configuration.

As illustrated in FIG. 2, the scan FF 111 includes a multiplexer 151 and an FF 152. As illustrated in FIG. 2, a clock pulse input to the scan FF 111 is supplied to a scan clock (SCK) input unit of the FF 152 and latches a value of a D terminal of the FF 152 at a rise of the clock pulse. The latched value is output through a Q terminal of the FF 152 and is supplied to an output Q terminal of the scan FF 111.

A scan-enable (SE) signal input to the scan FF 111 is a selector signal of the multiplexer 151 for selecting either of Din and SI (Scan In) of the multiplexer 151. An SI signal is selected when the SE is high whereas a Din signal is selected when the SE is low. The multiplexer 151 outputs a signal selected by the SE as an output signal of the multiplexer 151 and supplies it to the D terminal of the FF 152.

Next, a method for testing a semiconductor integrated circuit using a scan circuit will be described with reference to FIG. 1.

First, the scan-enable 133 of the semiconductor integrated circuit 100 is set to high, and preset data for a test is serially input from the scan-in 131 on a clock cycle basis, whereby values for the test are set in the scan FFs 111, 112, and 113. The scan FFs 111, 112, and 113 are serially connected by the foregoing scan chain. The scan FFs 111 to 113 connected by the scan chain perform a shift-register operation to transmit input data.

After that, the scan-enable 133 is set to low and one cycle of clock pulse is given to the SCK 132, so as to perform a capture operation. This capture operation causes computation results corresponding to values of the scan FFs connected before the combinational circuits to be stored in the scan FFs in the subsequent stage.

For example, the value stored in the scan FF 111 is supplied to the combinational circuit 121, and the output thereof is stored in the scan FF 112. At the same time, the value stored in the scan FF 112 is supplied to the combinational circuit 122, and the output thereof is stored in the scan FF 113. After such a capture operation has been performed, the scan-enable 133 is set to high again to apply a clock pulse to the SCK 132. With this process, the values stored in the scan FFs 111 to 113 are output to the outside through the scan-out 134 while a shift-register operation is performed.

This process is performed a plurality of times using various data for the test, and values output from the scan-out 134 are analyzed, whereby the combinational circuits are tested.

How the scan circuit including the wiring of the foregoing scan chain should be set in a semiconductor integrated circuit is determined in a stage of designing the semiconductor integrated circuit. Normally, the designing is automatically performed using a designing tool, and a process is performed so that efficient scan chain wiring is realized. As a result, it is highly possible that scan FFs that are mechanically close to each other are sequentially connected.

Therefore, in many cases, a plurality of FFs connected by a scan chain are inevitably set in a state where a plurality of scan FFs having equivalent functions are arranged in series. For example, in a case where a combinational circuit is an encrypting circuit and where a plurality of FFs for inputting key data or the like are set in the encrypting circuit, secret key information of n bits is input to a computation circuit from FFs the number of which is n. When such n FFs are connected by a scan chain, the scan chain may be serially connected in accordance with a bit string of the most significant bit (MSB) or least significant bit (LSB) of n-bit key information serving as secret information.

When the scan chain is connected in this manner, values output from the scan-out 134 are output in the connection order of the FFs, that is, bit data of MSB or LSB is output as is.

Also, after having been tested, the semiconductor integrated circuit is shipped after terminals such as the scan-in 131 and scan-out 134 are removed in many cases. However, the scan chain is not removed and is provided to a user. Thus, the scan chain remains in the shipped semiconductor integrated circuit. Therefore, if this scan chain is abused to check an output, information set in the FFs may be taken out by using the scan chain in which a normal data process was performed by using the circuit of the semiconductor integrated circuit. For example, secret information such as key information that is to be applied to an encryption process may leak.

In order to prevent such leakage of secret information, the following measures are taken, for example. At a shift to a scan test mode using a scan chain, scan FFs connected to the scan chain are initialized, whereby data held in the scan FFs is reset. Accordingly, even if an attacker causes the circuit to shift to the scan test mode during an operation, it is difficult to obtain and analyze important information about a key or the like from a scanned out value.

### SUMMARY OF THE INVENTION

As described above, if a scan chain is abused, secret information can leak from FFs connected to the scan chain. For example, in a case where several hundred bits of information to be scanned out includes important information about a key or the like and where a bit string is output in order from MSB or LSB, the following analysis of the key can be performed. An attacker obtains a pair of plaintext and ciphertext flowing in a public communication channel in advance, encrypts the given plaintext using values obtained by shifting a bit string output through scan out by 1 bit as candidate keys, and repeats comparison with the given ciphertext held in advance. This process enables the attacker to specify the key. In such a case where values scanned out via the scan chain are arranged in order from MSB or LSB, the key can be specified in a manner much easier than in specification based on a brute force attack disadvantageously.

Also, resetting the scan FFs connected to the scan chain at the shift to the scan test mode is insufficient as measures against leakage of secret information.

For example, the following problem exists. If secret information about a key or the like can be taken out through scan-out after the secret information is stored in scan FFs through several times of capture operation in the scan test mode after power-on, key data can be specified by analyzing scanned-out values using a search similar to that in the above-described method.

The scan test is necessary as a failure detecting system for a semiconductor integrated circuit, and is incorporated into the semiconductor integrated circuit unless in special circumstances. A semiconductor integrated circuit having a security function is not exceptional. Particularly, however, a semiconductor integrated circuit having a security function should have a mechanism in which internal information about a key or the like is not easily specified, with detection of failure by a scan circuit being realized. That is, the following mechanism is necessary to be realized: when a bit string including key information is output through scan-out, a rightful executor who executes a test can easily analyze the output value, but it is difficult for an attacker who does not know a circuit configuration to specify the key even if the attacker analyzes the value obtained through scan-out.

However, as described above, the configuration according to the related art has a problem in that measures against leakage of secret information such as key data are insufficient because values stored in scan FFs connected to a scan chain can be output to be analyzed.

Accordingly, it is desirable to provide a semiconductor integrated circuit that realizes prevention of leakage of information using a scan chain of the semiconductor integrated circuit, an information processing apparatus, an output data diffusion method, and a program.

According to an embodiment of the present invention, there is provided a semiconductor integrated circuit including a scan chain configured to serve as a connection path used for testing the semiconductor integrated circuit and connect a plurality of flip-flops, and an interleave circuit provided at an output portion of the scan chain. The interleave circuit includes a plurality of branches including different numbers of stages of storage elements, a selector configured to select one of the plurality of branches serving as an input/output branch that performs input of data from the scan chain and output of data from the interleave circuit, and a selector controller configured to execute a process of switching among the plurality of branches to select the input/output branch at every predetermined timing.

The selector controller may execute a process of switching among the plurality of branches to select the input/output branch every time data is input from the scan chain.

The selector controller may execute a process of switching among the plurality of branches in accordance with a preset switching sequence.

The semiconductor integrated circuit may further include a memory configured to store a branch selection table used for selecting one of the plurality of branches serving as the input/output branch that performs input of data from the scan chain and output of data from the interleave circuit, memory addresses and branch identifiers being associated with each other in the branch selection table, a counter configured to count a count value at every predetermined timing, and a control circuit including a controller configured to output, from the branch selection table, a branch identifier corresponding to a memory address corresponding to a count value of the counter to the selector controller of the interleave circuit. The selector controller may execute a process of selecting a branch corresponding to the branch identifier input from the control circuit as the input/output branch.

The branch selection table may have a setting in which the branch identifiers are randomly associated with the memory addresses. The selector controller may execute a process of randomly selecting the input/output branch in accordance with branch identifiers in a random sequence input from the control circuit.

The semiconductor integrated circuit may further include an initializing unit configured to set initial values of the storage elements included in the plurality of branches.

The initializing unit may include a random number generator and may execute an initialization process of inputting random numbers generated by the random number generator as initial values of the storage elements included in the plurality of branches.

The storage elements may be registers.

According to another embodiment of the present invention, there is provided an information processing apparatus including the semiconductor integrated circuit.

According to another embodiment of the present invention, there is provided an output data diffusion method that is executed in an information processing apparatus. The method includes the step of executing, in an interleave circuit, a process of diffusing an output from a scan chain configured to serve as a connection path used for testing a semiconductor integrated circuit and connect a plurality of flip-flops. The step of executing includes sequentially switching among a plurality of branches including different numbers of stages of storage elements to select one of the plurality of branches serving as an input/output branch that performs input of data from the scan chain and output of data from the interleave circuit.

According to another embodiment of the present invention, there is provided a program causing an information processing apparatus to execute an output data diffusion process. The program includes the step of executing, in an interleave circuit, a process of diffusing an output from a scan chain configured to serve as a connection path used for testing a semiconductor integrated circuit and connect a plurality of flip-flops. The step of executing includes sequentially switching among a plurality of branches including different numbers of stages of storage elements to select one of the plurality of branches serving as an input/output branch that performs input of data from the scan chain and output of data from the interleave circuit.

Additionally, the program according to an embodiment of the present invention can be provided to an image processing apparatus or a computer system capable of executing various program codes via a computer-readable storage medium or communication medium. By providing such a program in a computer-readable manner, processes are realized in accordance with the program in the image processing apparatus or the computer system.

Further features and advantages of the embodiments of the present invention will become apparent from the following detailed description based on embodiments and attached drawings. In this specification, a system means a logical set of a plurality of apparatuses, and the apparatuses having respective configurations are not necessarily in the same casing.

According to an embodiment of the present invention, an interleave circuit that performs a data diffusion process is set at an output portion of a scan chain that is set as a path for testing an integrated circuit, such as a large scale integration (LSI). The interleave circuit includes a plurality of branches including different numbers of stages of registers and a selector configured to select a branch that performs input of data from the scan chain and output of data, and executes control to sequentially change selected branches. With this configuration, an output bit sequence from the scan chain is output to the outside while being diffused, so that leakage of data stored in flip-flops can be prevented.

### BRIEF DESCRIPTION OF THE DRAWINGS

FIG. 1 illustrates a scan chain in a semiconductor integrated circuit;

FIG. 2 illustrates a configuration of a scan FF having a flip-flop connected to the scan chain;

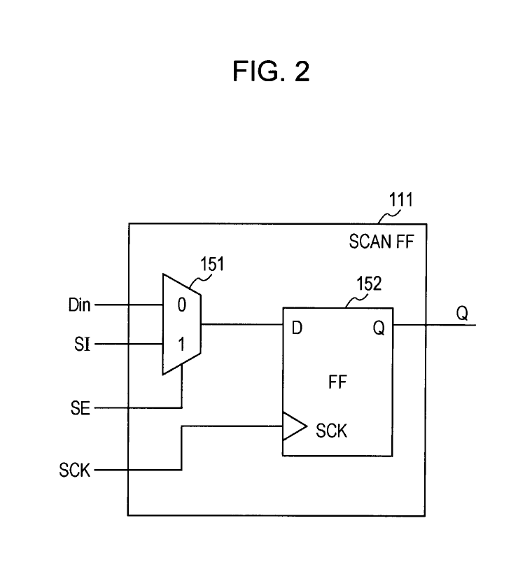

FIG. 3 illustrates a configuration example of a semiconductor integrated circuit according to a first embodiment of the present invention;

FIG. 4 illustrates a configuration example of an interleave circuit that is set in the semiconductor integrated circuit according to the first embodiment of the present invention;

FIG. 5 illustrates an example of a data diffusion process sequence applying the interleave circuit in the semiconductor integrated circuit according to the first embodiment of the present invention;

FIG. 6 illustrates a configuration example of a semiconductor integrated circuit according to a second embodiment of the present invention;

FIG. 7 illustrates a configuration example of an interleave circuit and a control circuit that are set in the semiconductor integrated circuit according to the second embodiment of the present invention;

FIG. 8 illustrates a configuration example of a branch selection table stored in a ROM in the control circuit that is set in the semiconductor integrated circuit according to the second embodiment of the present invention;

FIG. 9 illustrates an example of a data diffusion process sequence applying the interleave circuit in the semiconductor integrated circuit according to the second embodiment of the present invention;

FIG. 10 illustrates a configuration example of a semiconductor integrated circuit according to a third embodiment of the present invention;

FIG. 11 illustrates a configuration example of an interleave circuit and an initializing unit that are set in the semiconductor integrated circuit according to the third embodiment of the present invention; and

FIG. 12 illustrates an example of a data diffusion process sequence applying the interleave circuit in the semiconductor integrated circuit according to the third embodiment of the present invention.

### DESCRIPTION OF THE PREFERRED EMBODIMENTS

Hereinafter, a semiconductor integrated circuit, an information processing apparatus, an output data diffusion method, and a program according to embodiments of the present invention will be described in detail with reference to the attached drawings. The description will be given in accordance with the following items.

1. Configuration and process according to a first embodiment of the present invention 2. Configuration and process according to a second embodiment of the present invention 3. Configuration and process according to a third embodiment of the present invention

### 1. Configuration and Process According to a First Embodiment of the Present Invention

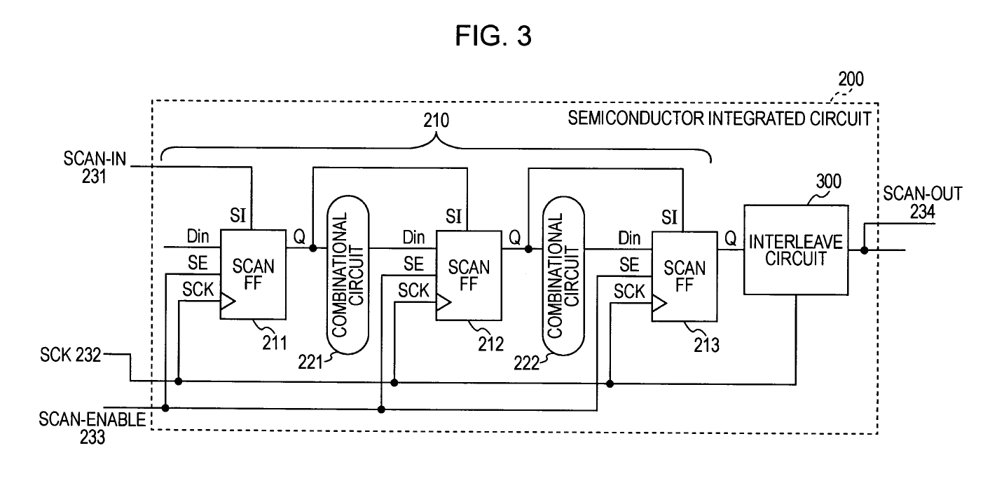

A first embodiment of the present invention will be described with reference to FIG. 3, etc. FIG. 3 illustrates a semiconductor integrated circuit 200 according to the first embodiment of the present invention.

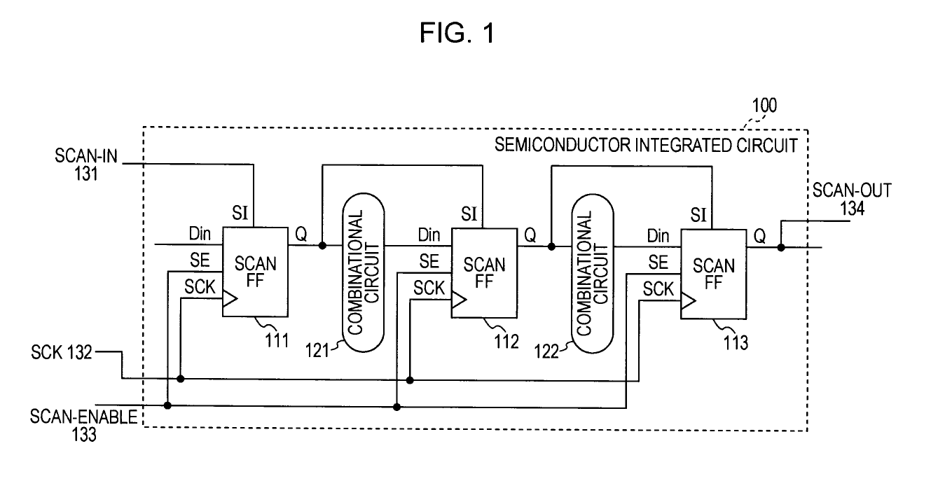

A circuit portion 210 of the semiconductor integrated circuit 200 according to this embodiment illustrated in FIG. 3 is similar to the circuit described above with reference to FIG. 1. That is, the circuit portion 210 includes combinational circuits 221 and 222, each composed of a plurality of circuit elements that execute various data processes and computation processes, and scan flip-flops (FFs) 211 to 213 for holding and transferring data to be input to the combinational circuits 221 and 222 and data output from the combinational circuits 221 and 222.

Each of the scan FFs 211 to 213 illustrated in FIG. 3 may include a plurality of scan FFs, instead of a single scan FF. A connection line for connecting the scan FFs 211 to 213 illustrated in FIG. 3 is set as a scan chain for testing the circuit and is used for a test or the like in a manufacturing stage of the semiconductor integrated circuit.

The configuration of external terminals of the semiconductor integrated circuit 200 is also similar to that described above with reference to FIG. 1, and includes a scan-in 231, a scan clock (SCK) 232, a scan-enable 233, and a scan-out 234.

Unlike the configuration illustrated in FIG. 1, the semiconductor integrated circuit 200 illustrated in FIG. 3 includes an interleave circuit 300. The interleave circuit 300 is set in the previous stage of the scan-out 234. Specifically, the interleave circuit 300 is provided in the previous stage of the scan-out 234, which is on the output unit side of the scan FF 213 positioned at the end of the scan chain connecting the scan FFs 211 to 213 in the semiconductor integrated circuit 200.

The interleave circuit 300 receives an output of the scan FF 213, executes an interleave process of diffusing input data, and outputs processed data through the scan-out 234.

The external terminals of the semiconductor integrated circuit 200 are the same as those of the semiconductor integrated circuit 100 illustrated in FIG. 1, and these terminals are used in a scan test. In the scan test, a final output bit sequence output from the scan FFs 211 to 213 and the combinational circuits 221 and 222 is output through the scan-out 234 via the interleave circuit 300 for scan-out after a capture operation.

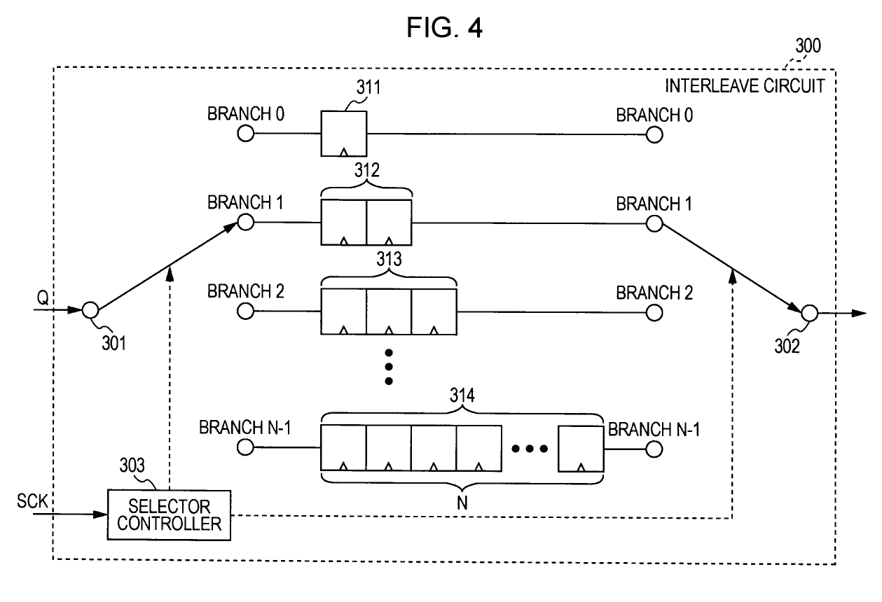

The details of the interleave circuit 300 are illustrated in FIG. 4. As illustrated in FIG. 4, the interleave circuit 300 includes selectors 301 and 302 having branches the number of which is N on both input and output sides, and a selector controller 303 sequentially selects branches on a clock cycle basis.

That is, every time a clock pulse is applied to the SCK 232, the selector controller 303 sequentially selects a branch 0, a branch 1, a branch 2, . . . , and a branch N-1 in accordance with the clock pulses. After the branch N-1 has been selected, the foregoing operation is repeated from the branch 0. Registers 311 to 314 are disposed between the selectors 301 and 302. Note that, although the resistors are used in this embodiment, other various storage elements such as memories may also be used.

Only four branches are illustrated in FIG. 4, but actually N branches including the branches 0 to N-1 are set. The number of stages of the register in each branch is as follows: one for the register 311; two for the register 312; three for the register 313; and N for the register 314 in the last branch N-1, with increases by one. In this way, the individual branches include different numbers of stages of registers.

That is, a register having i+1 stages is connected to each of the branches i (i=0, 1, . . . , and N-1).

The register in each branch functions as a shift register. An output value from the selector 301 is input to the register in the branch selected by the selector 301. When a clock pulse is applied from the SCK 232, the register performs a shift operation, that is, stores an already-stored value in an adjoining stage (a right-adjoining stage in FIG. 4), and also a value supplied from the selector 301 is stored. That is, the register performs a first-in first-out (FIFO) operation. At this time, the registers in the branches not selected by the selectors 301 and 302 hold values therein regardless of the SCK.

Hereinafter, a function of the interleave circuit 300 will be described in detail. The following description will be given under the assumption that the number of branches N=4.

The selector controller 303 causes the selectors 301 and 302 to select the same branch in synchronization per clock cycle, in the order of 0, 1, 2, 3, 0, 1, 2, 3, 0, As described above, an input is supplied to the register in the branch selected by the selector 301, and the register performs a FIFO operation on a clock cycle basis.

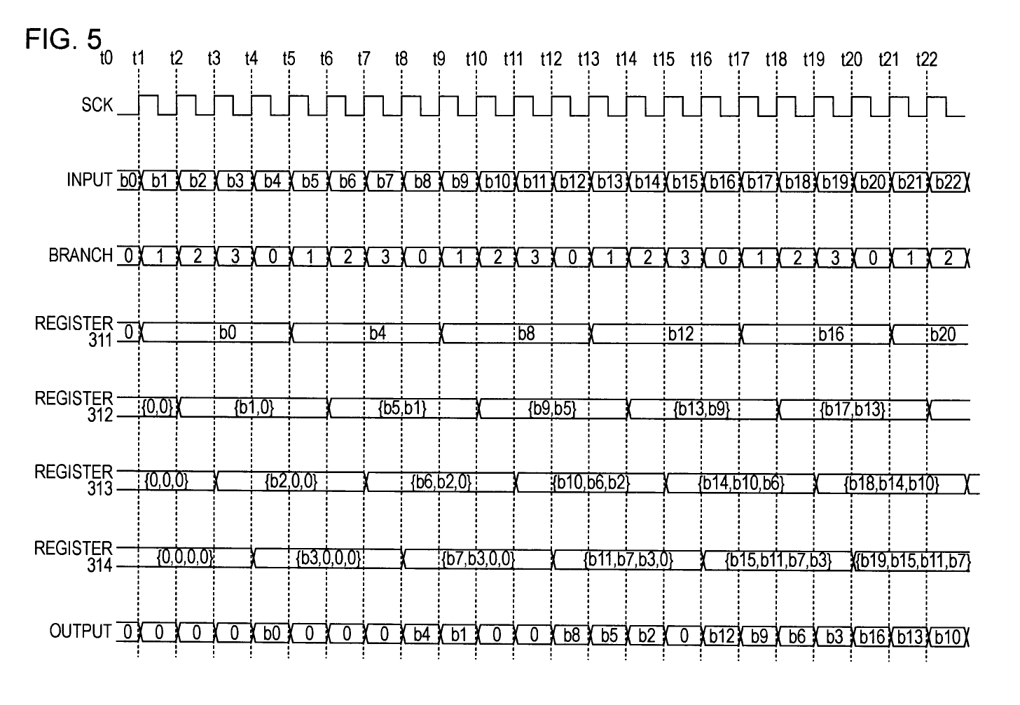

The interleave circuit 300 executes a diffusion process on a bit sequence, which is input as a final output of the scan chain. How the bit sequence is diffused by the interleave circuit 300 will be described with reference to the timing chart illustrated in FIG. 5. First, signals illustrated in FIG. 5 will be described.

“SCK” represents scan clock pulses.

“Input” represents an input value to the selector 301. The bit sequence thereof is {b0, b1, b2, b3, b4, b5, b6, b7, . . . }.

“Branch” represents the branch selected by the selectors 301 and 302.

“Register 311”, “register 312”, “register 313”, and “register 314” represent values stored therein respectively, and the initial state thereof is 0 in all the registers for simplicity.

“Output” represents an output of the selector 302, which is an output of the interleave circuit 300.

First, at time t0, the registers 311 to 314 in the interleave circuit 300 are initialized with 0. The input selector 301 is supplied with a first output bit from the scan chain. This corresponds to b0 of “input” illustrated in FIG. 5. The selectors 301 and 302 are selecting the branch 0. However, at time t0, the input value b0 has not stored in the register 311 via the branch 0 of the selector 301. A storage process is performed when a clock pulse is applied. Therefore, the output of the interleave circuit 300 is the value of the register 311 connected to the branch 0 that is selected by the selector 302. That is, 0 is output.

Subsequently, when a clock pulse is applied to the SCK at time t1, the input value b0 to the selector 301 is stored in the register 311 via the branch 0 of the selector 301. The values in the other registers 312, 313, and 314 (all the values are 0) are held therein. At the same time, the selectors 301 and 302 select the branch 1, whereby b1 is supplied to the selector 301. Since the selector 302 is selecting the branch 1, the output thereof is a value in the right-end stage of the register 312 connected to the branch 1, that is, 0.

Furthermore, when a clock pulse is applied to the SCK at time t2, the register 312 executes a shift operation, and the input value b1 to the selector 301 is stored in the left-end stage of the register 312 via the branch 1 of the selector 301. As a result, {b1, 0} is stored in the register 312. The values in the other registers 311, 313, and 314 are held therein. At the same time, the selectors 301 and 302 select the branch 2, and b2 is supplied to the selector 301. Since the selector 302 is selecting the branch 2, the output thereof is the value in the right-end stage of the register 313 connected to the branch 2, that is, 0.

Likewise, at time t3, the input value b2 to the selector 301 is stored in the left-end stage of the register 313, so that {b2, 0, 0} is obtained, and the value in the right-end stage of the register 314, that is, 0, is output. At time t4, the input value b3 to the selector 301 is stored in the left-end stage of the register 314, so that {b3, 0, 0, 0} is obtained, and the selection by the selectors 301 and 302 returns to the branch 0. Thus, the value in the register 311, that is, b0 is output. The operation performed at time t5 and thereafter can be clearly understood from the timing chart in FIG. 5, and thus the description thereof will be omitted.

As can be understood from the timing chart in FIG. 5, an input bit sequence and an output bit sequence of the interleave circuit 300 have the following setting.

An input bit sequence {b0, b1, b2, b3, b4, . . . } is processed by the interleave circuit 300, thereby becoming an output bit sequence {0, 0, 0, 0, b0, 0, 0, 0, b4, b1, 0, 0, b8, b5, b2, 0, b12, b9, b6, b3, b16, . . . }.

In this way, bits adjoining each other when being input to the interleave circuit 300 are diffused by the process performed by the interleave circuit 300. That is, the bit sequence input to the interleave circuit 300 is output therefrom as a diffused bit sequence that is different from the input bit sequence.

Incidentally, a rightful executor who executes a scan test knows an algorithm of an interleave process executed in the interleave circuit 300. Therefore, the executor executes an algorithm for executing a reverse process of the interleave process using software, for example. With this process, a test process can be performed by obtaining a bit sequence before interleave.

On the other hand, a malignant analyzer does not know the algorithm of the interleave process, so that the analyzer analyzes values held in the scan FFs connected to the scan chain on the basis of only the data diffused by the interleave circuit.

Hereinafter, under the assumption that encryption key data, which is secret information, is stored in the scan FFs connected to the scan chain, considerations are performed about the number of trials necessary to search for a key in a case of executing key analysis using data that is diffused by the interleave circuit. Here, it is assumed for simplicity that the value scanned out via the scan chain is a bit string of 256 bits and that a 128-bit key is contained in the bit string.

Sequential 128 bits are taken out as a candidate key from the end of a bit string that is scanned out from a circuit without an interleave circuit according to the related art, for example, from the semiconductor integrated circuit 100 illustrated in FIG. 1, and values obtained through shifts by one bit from the 128 bits are regarded as candidate keys, respectively. Accordingly, 128 candidate keys are obtained in total. For the 128 candidate keys, given plaintexts are encrypted and comparison with a given ciphertext that is already held is repeated, whereby the key can be easily specified from the scanned-out bit sequence with 128 trials at the maximum.

In contrast, analysis of key data using a bit sequence diffused by the interleave circuit 300, described above with reference to FIGS. 3 to 5, is performed in the following manner. When it is assumed that an attacker does not know measures taken on a scan circuit, i.e., that the attacker does not know the interleave circuit 300 is provided, it is necessary for the attacker to at least examine all scanned-out candidate keys of 256 bits to 128 bits.

In this case, values that are possible as a key are values obtained from scanned out values of 256 bits without overlaps in consideration of the order of 128 bits, and thus the number of trials of examining a key performed by the attacker is ₂₅₆P₁₂₈>>2¹²⁸>>128. In such a configuration including the interleave circuit 300 described above with reference to FIGS. 3 to 5, the number of trials can be significantly increased compared to the related art.

Next, the condition is slightly eased, and it is assumed that the attacker knows that bit diffusion measures using the interleave circuit are taken on the scan circuit but does not know the number of branches N.

In this case, the attacker assumes the number of branches N of the interleave circuit to constitute the inverse function thereof in advance, and inputs a bit sequence obtained from the scan-out into the inverse function of the interleave circuit in which N was assumed, thereby obtaining candidate bit sequences at output of the scan-out (SO), that is, undiffused candidate bit sequences. Then, an attack similar to that of the related art is applied to the obtained candidate bit sequences, whereby candidate keys are obtained. Here, it is necessary for the attacker to perform the foregoing attack procedure on all the assumed numbers of branches 2 to N, and thus the number of trials necessary to be performed by the attacker is 128(N-1)≧128. Therefore, in a case where N>2, the number of trials performed by the attacker can be increased compared to the related art.

On the other hand, a manufacturer capable of duly performing a scan test knows that the interleave circuit is applied and also knows the number of branches N, as described above, and thus can constitute the inverse function of the interleave circuit in advance. Therefore, at the scan test, the manufacturer can perform a normal scan test by converting a scanned-out bit sequence into a bit sequence before diffusion by using the inverse function.

As described above, the semiconductor integrated circuit 200, in which the interleave circuit 300 described above with reference to FIGS. 3 to 5 is set in the previous stage of the scan-out in the scan chain, is capable of significantly increasing the difficulty of analyzing bit strings held in scan FFs from a scanned-out bit sequence. Therefore, in the semiconductor integrated circuit that handles highly confidential data, leakage of secret information via the scan chain can be effectively prevented.

In this embodiment, the interleave circuit 300 is configured using selectors and registers, as illustrated in FIG. 4. However, other circuit configurations may also be used instead of such a combination of selectors and registers, as long as a similar data diffusion function can be realized. For example, a computation circuit for performing a data converting process and an encrypting circuit may be applied.

### 2. Configuration and Process According to a Second Embodiment of the Present Invention

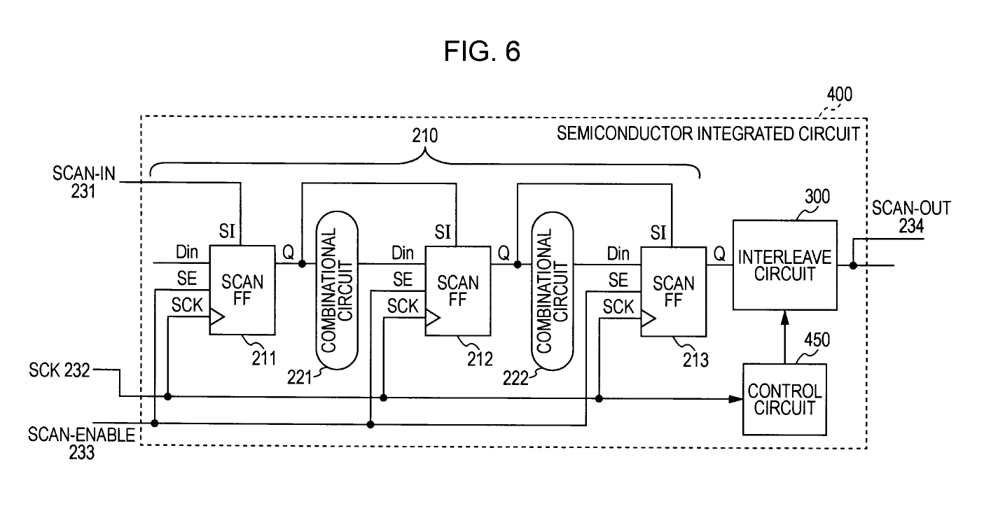

Next, a second embodiment of the present invention will be described with reference to FIG. 6, etc. FIG. 6 illustrates a semiconductor integrated circuit 400 according to the second embodiment of the present invention.

A circuit portion 210 of the semiconductor integrated circuit 400 according to this embodiment illustrated in FIG. 6 is similar to the circuit described above with reference to FIG. 1. That is, the circuit portion 210 includes combinational circuits 221 and 222, each composed of a plurality of circuit elements that execute various data processes and computation processes, and scan flip-flops (FFs) 211 to 213 for holding and transferring data to be input to the combinational circuits 221 and 222 and data output from the combinational circuits 221 and 222.

Each of the scan FFs 211 to 213 illustrated in FIG. 6 may include a plurality of scan FFs, instead of a single scan FF. A connection line for connecting the scan FFs 211 to 213 illustrated in FIG. 6 is set as a scan chain for testing the circuit and is used for a test or the like in a manufacturing stage of the semiconductor integrated circuit.

The configuration of external terminals of the semiconductor integrated circuit 400 is also similar to that described above with reference to FIG. 1, and includes a scan-in 231, a scan clock (SCK) 232, a scan-enable 233, and a scan-out 234.

The semiconductor integrated circuit 400 illustrated in FIG. 6 includes an interleave circuit 300, which is similar to that in the first embodiment described above with reference to FIGS. 3 to 5. The interleave circuit 300 is set in the previous stage of the scan-out 234. Specifically, the interleave circuit 300 is provided in the previous stage of the scan-out 234, which is on the output unit side of the scan FF 213 positioned at the end of the scan chain connecting the scan FFs 211 to 213 in the semiconductor integrated circuit 400.

The interleave circuit 300 receives an output of the scan FF 213, executes an interleave process of diffusing input data, and outputs processed data through the scan-out 234.

The semiconductor integrated circuit 400 according to this embodiment illustrated in FIG. 6 further includes a control circuit 450. The control circuit 450 performs control of selectors in the interleave circuit 300, that is, control of selecting branches.

The external terminals of the semiconductor integrated circuit 400 are the same as those of the semiconductor integrated circuit 100 illustrated in FIG. 1, and these terminals are used in a scan test. In the scan test, a final output bit sequence output from the scan FFs 211 to 213 and the combinational circuits 221 and 222 is output through the scan-out 234 via the interleave circuit 300 for scan-out after a capture operation.

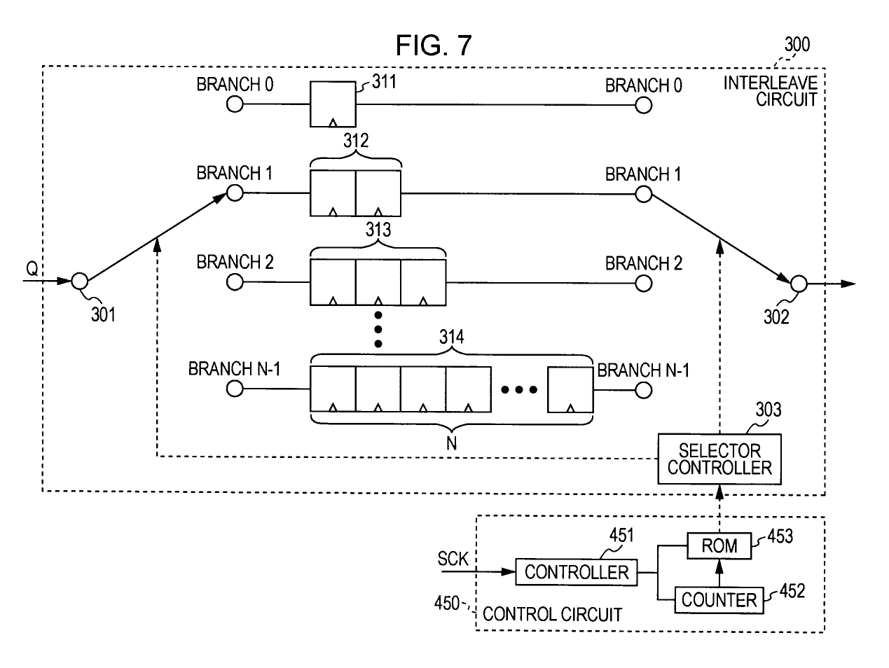

A specific configuration example of the interleave circuit 300 and the control circuit 450 is illustrated in FIG. 7. The control circuit 450 includes a controller 451, a counter 452, and a read only memory (ROM) 453. The ROM 453 is a storage unit that stores a branch selection table describing the order of selecting branches by selectors 301 and 302 of the interleave circuit 300.

Hereinafter, a description will be given under the assumption that the number of branches N=4.

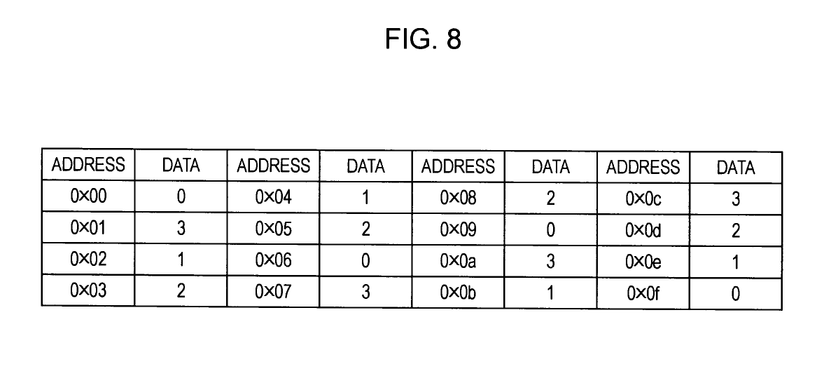

FIG. 8 illustrates an example of the branch selection table that is stored in the ROM 453 in case where the number of elements except the elements corresponding to addresses of the branch selection table is defined as M, the number of branches N=4, and the number of elements M=16. As illustrated in FIG. 8, the branch selection table is a list in which branch numbers (data) from 0 to 3 are stored in random order in the addresses of the branch selection table stored in the ROM 453.

On the other hand, the counter 452 is a base-M counter that counts from 0 to M-1. Under control performed by the controller 451, the counter 452 updates a count value in accordance with the SCK. Under control performed by the controller 451, count values (0 to M-1) generated by the counter 452 are supplied as addresses to the ROM 453.

The ROM 453 selects addresses corresponding to the count values (0 to M-1) supplied from the counter 452 from the branch selection table illustrated in FIG. 8, and obtains branch numbers (data) that are recorded while being associated with the selected addresses. The obtained branch numbers (data) are supplied to the selector controller 303 of the interleave circuit 300 on a clock cycle basis under control performed by the controller 451.

The selector controller 303 of the interleave circuit 300 uses the branch numbers supplied from the control circuit 450 as select signals of the selectors 301 and 302. With this process, the branch numbers set in the branch selection table stored in the ROM 453 of the control circuit 450 are sequentially supplied to the interleave circuit 300.

In a case where the branch selection table illustrated in FIG. 8 is used, the branch numbers 0, 3, 1, 2, 1, 2, 0, 3, . . . are supplied to the interleave circuit 300 on a clock cycle basis. The selector controller 303 of the interleave circuit 300 sequentially uses the branch numbers supplied from the control circuit 450 as select signals of the selectors 301 and 302 on a clock cycle basis.

By causing the branch selection table stored in the ROM 453 to have the setting illustrated in FIG. 8, that is, by causing the branch selection order to be random, an operation can be performed such that the branches in the selectors 301 and 302 are selected in seemingly random order.

Hereinafter, a description will be given about an operation of the control circuit 450 according to the second embodiment and an operation sequence of the interleave circuit 300 associated therewith. Now, it is assumed for simplicity that N=4 and M=16 and that the branch selection table illustrated in FIG. 8 is stored in the ROM 453 of the control circuit 450. In this case, the counter 452 functions as a hexadecimal counter.

In the control circuit 450, the initial value of the counter 452 (here, the value is assumed to be 0) is supplied to the address of the ROM 453, and then the value corresponding to an address 0x00 of the branch selection table, that is, 0, is output from the ROM 453. Accordingly, the branch 0 is selected by the selectors 301 and 302 in the interleave circuit 300.

Subsequently, when an SCK is input, the value of the counter 452 is incremented and 1 is supplied to the ROM 453. Accordingly, the ROM 453 outputs the value corresponding to an address 0x01 of the branch selection table, that is, 3. As s result, the branch 3 is selected by the selectors 301 and 302.

Thereafter, the control circuit 450 executes the same operation every time an SCK is input. Accordingly, the selectors 301 and 302 select branches in accordance with the branch selection table stored in the ROM 453. Thus, by causing the selection order described in the branch selection table to be random, an operation can be performed such that the branches are selected in seemingly random order.

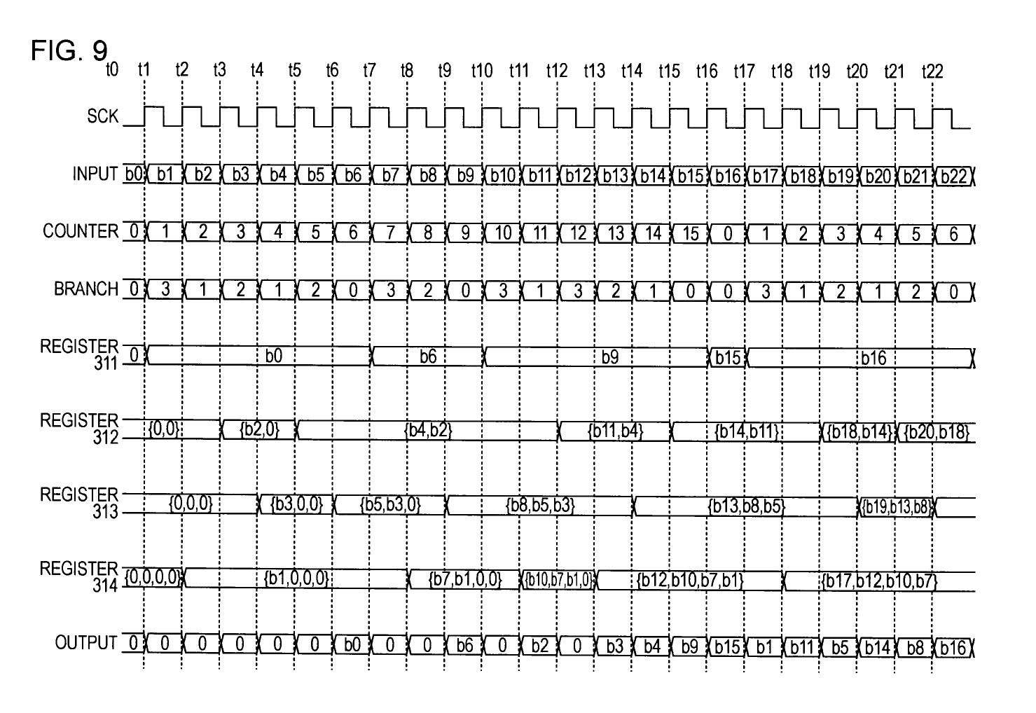

Now, a description will be given with reference to the timing chart in FIG. 9 about a diffusion process based on the above-described operation, that is, how a bit sequence {b0, b1, b2, b3, . . . } input to the interleave circuit 300 is diffused. The names of signals illustrated in FIG. 9 are similar to those illustrated in FIG. 5 corresponding to the above-described first embodiment. As in FIG. 5, it is assumed for simplicity that the initial value of each of the registers and the counter is 0.

At time t0, the first output bit from the scan chain is supplied to the input selector 301. This is b0 of “input” illustrated in FIG. 9. At this time, the output from the counter 452 of the control circuit 450 is the initial value 0, so that the output of the ROM 453 is also 0 and that the selectors 301 and 302 select the branch 0. However, at time t0, the input value b0 has not been stored in the register 311 via the branch 0 of the selector 301. A storage process is performed when a clock pulse is applied. Thus, the output of the interleave circuit 300 is the value of the register 311 connected to the branch 0 that is selected by the selector 302. That is, 0 is output.

Subsequently, when a clock pulse is applied to the SCK at time t1, the input value b0 to the selector 301 is stored in the register 311 via the branch 0 of the selector 301. At this time, the values in the registers 312, 313, and 314 are held therein (all the values are 0). At the same time, the counter 452 is incremented to 1. This corresponds to an address 0x01 of the branch selection table illustrated in FIG. 8.

The branch number 3 corresponding to the address 0x01 of the branch selection table stored in the ROM 453 is supplied to the selector controller 303 of the interleave circuit 300. Accordingly, the selectors 301 and 302 select the branch 3, and the output of the selector 302 is the value in the right-end stage of the register 314, that is, 0. Also, b1 is supplied to the selector 301 and is then supplied to the register 314.

Furthermore, when a clock pulse is applied to the SCK at time t2, the resister 314 performs a 1-bit shift operation, and b1 is stored in the left-end stage of the register 314 via the branch 3 of the selector 301. As a result, the value of the register 314 is {b1, 0, 0, 0}. At the same time, the counter 452 is incremented to 2. Then, the ROM 453 supplies 1 to a select signal of the selectors 301 and 302. Accordingly, the selectors 301 and 302 select the branch 1, the output of the selector 302 is the value in the right-end stage of the register 312, that is, 0, and b2 is supplied to the selector 301.

An operation is performed in the same manner at time t3 and thereafter. The operation can be understood from the timing chart in FIG. 9, and thus the description thereof is omitted.

As can be understood from the timing chart in FIG. 9, an input bit sequence and an output bit sequence of the interleave circuit 300 have the following setting.

An input bit sequence {b0, b1, b2, b3, b4, . . . } is processed by the interleave circuit 300, thereby becoming an output bit sequence {0, 0, 0, 0, 0, 0, b0, 0, 0, b6, 0, b2, 0, b3, b4, b9, b15, b1, b11, b5, . . . }.

In this way, bits adjoining each other when being input to the interleave circuit 300 are diffused by the process performed by the interleave circuit 300. That is, the bit sequence input to the interleave circuit 300 is output therefrom as a diffused bit sequence that is different from the input bit sequence.

Incidentally, a rightful executor who executes a scan test knows an algorithm of an interleave process executed in the interleave circuit 300. Therefore, the executor executes an algorithm for executing a reverse process of the interleave process using software, for example. With this process, a test process can be performed by obtaining a bit sequence before interleave.

On the other hand, a malignant analyzer does not know the algorithm of the interleave process, so that the analyzer analyzes values held in the scan FFs connected to the scan chain on the basis of only the data diffused by the interleave circuit.

Hereinafter, under the assumption that encryption key data, which is secret information, is stored in the scan FFs connected to the scan chain, considerations are performed about the number of trials necessary to search for a key in a case of executing key analysis using data that is diffused by the interleave circuit. Here, it is assumed for simplicity that the value scanned out via the scan chain is a bit string of 256 bits and that a 128-bit key is contained in the bit string.

First, considerations are performed about a case where an attacker does not know the measures taken on the scan circuit. In this case, as in the first embodiment, it is necessary for the attacker to execute trials for all possible candidate keys from a scanned-out output, and thus the maximum number of trials is ₂₅₆P₁₂₈. Therefore, the number of trials performed by the attacker can be significantly increased as in the first embodiment.

Next, considerations are performed about a case where the attacker knows that an interleave circuit is used as measures on the scan circuit but does not know the number of branches N and the branch selection table stored in the ROM. In this case, as in the first embodiment, it is necessary for the attacker to search for the number of branches N in the interleave circuit and search for the branch selection order in the branch selection table stored in the ROM.

Hereinafter, a procedure executed by the attacker will be described in detail. First, the attacker assumes that the number of branches is i, and performs trials on all combinations that can be used as branch selection order in the table stored in the ROM. Therefore, the number of trials for returning a diffused bit sequence to an output from the scan-out is i! at the maximum with respect to the assumed number of branches i. In addition, it is necessary for the attacker to sequentially search for a 128-bit key from a 256-bit output in each of the foregoing trials, and thus the number of trials necessary to be performed by the attacker is 128×i! at the maximum with respect to the assumed number of branches i. Furthermore, it is necessary for the attacker to apply the foregoing trial on all candidates from 2 to N as the number of branches i. Thus, the maximum number of trials that should be performed by the attacker is as follows.

$$128 {\sum }_{i = 2}^{N} i !$$

Also, the number of elements M of the branch selection table stored in the ROM is normally equal to or larger than N(M≧N). In this case, the maximum number of trials is as follows.

$$128 {\sum }_{i = 2}^{N} i ! ⌊ \frac{M}{i} ⌋$$

Also, in the branch selection table illustrated in FIG. 8, elements are selected so that overlap does not occur in the branch selection order. Alternatively, the elements may be selected so that overlap occurs in order to increase the number of trials performed by the attacker. In this case, the maximum number of trials further increases as follows.

$$128 {\sum }_{i = 2}^{N} {i}^{M}$$

As described above, with the application of the configuration of the second embodiment in which branches can be randomly selected, the number of trials performed by the attacker can be further increased compared to the above-described first embodiment. Additionally, in the second embodiment, it is necessary for the attacker to specify individual elements in the branch selection table, in addition to the number of branches N of the interleave circuit. Furthermore, since the number of elements M of the branch selection table can be increased in accordance with the size of the ROM, the number of trials performed by the attacker can be increased even when the attacker knows that the interleave circuit is used.

On the other hand, a manufacturer capable of duly performing a scan test knows that the interleave circuit is applied and also knows the number of branches N and the content of the branch selection table, as described above, and thus can constitute the inverse function of the interleave circuit in advance. Therefore, at the scan test, the manufacturer can perform a normal scan test by converting a scanned-out bit sequence into a bit sequence before diffusion by using the inverse function.

In the above-described second embodiment, signals for selecting branches are generated by using the branch selection table stored in the ROM, which is a form of performing an operation such that the branches are selected in seemingly random order. However, as long as the number of trials that should be performed by an attacker can be increased by randomly selecting branches, the method therefore is not limited. For example, instead of using the counter and the ROM, a configuration of generating branch selection signals using a random number generator may be applied.

### 3. Configuration and Process According to a Third Embodiment of the Present Invention

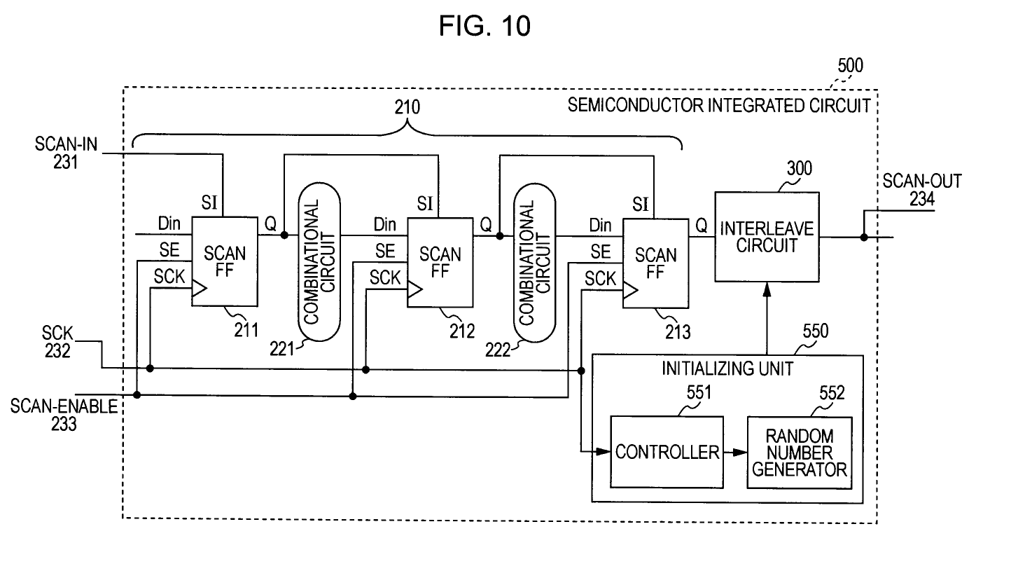

Finally, a third embodiment of the present invention will be described with reference to FIG. 10, etc. FIG. 10 illustrates a semiconductor integrated circuit 500 according to the third embodiment of the present invention.

The third embodiment is an embodiment that can be applied in combination with the above-described first or second embodiment. In the above-described first and second embodiments, a bit sequence is diffused by using the interleave circuit, which makes it difficult for an attacker to analyze important information included in the bit sequence, such as a key.

However, when the process examples described in the first and second embodiments are applied as is, there is a possibility that the attacker can specify the key with trials the number of which is much smaller than the number described above in the first and second embodiments. This will be described in detail using the first embodiment as an example.

In the first embodiment, the individual registers in the interleave circuit are initialized with a fixed value, such as 0, for simplicity. In a case where such an initialization setting is performed, an identical value such as 0 or 1 is output until b0, which is the first bit of a diffused bit sequence, is output. Here, it can be understood from the characteristic of the interleave circuit described in the first embodiment that the first N bit output from the scan-out serves as the initial value of the individual registers existing in the interleave circuit. Thus, the attacker can estimate the number of branches N in the interleave circuit by measuring the number of outputs of fixed values output from the start of a scan test. Therefore, the initial values of the individual registers should not be fixed in a case where the first and second embodiments are actually applied. A configuration satisfying this condition will be described below as the third embodiment.

In the third embodiment, the registers in the interleave circuit are initialized with a random number. That is, the third embodiment serves as an additional function of the first and second embodiments.

FIG. 10 illustrates a semiconductor integrated circuit 500 according to the third embodiment of the present invention. The configuration illustrated in FIG. 10 is different from the semiconductor integrated circuit 200 according to the first embodiment described above with reference to FIG. 3 in that an initializing unit 550 is added.

A circuit portion 210 of the semiconductor integrated circuit 500 according to this embodiment illustrated in FIG. 10 is similar to the circuit described above with reference to FIG. 1. That is, the circuit portion 210 includes combinational circuits 221 and 222, each composed of a plurality of circuit elements that execute various data processes and computation processes, and scan flip-flops (FFs) 211 to 213 for holding and transferring data to be input to the combinational circuits 221 and 222 and data output from the combinational circuits 221 and 222.

An interleave circuit 300 is a circuit that executes a process similar to that performed by the interleave circuit according to the above-described first embodiment. The interleave circuit 300 receives an output of the scan FF 213, executes an interleave process of diffusing input data, and outputs processed data through a scan-out 234.

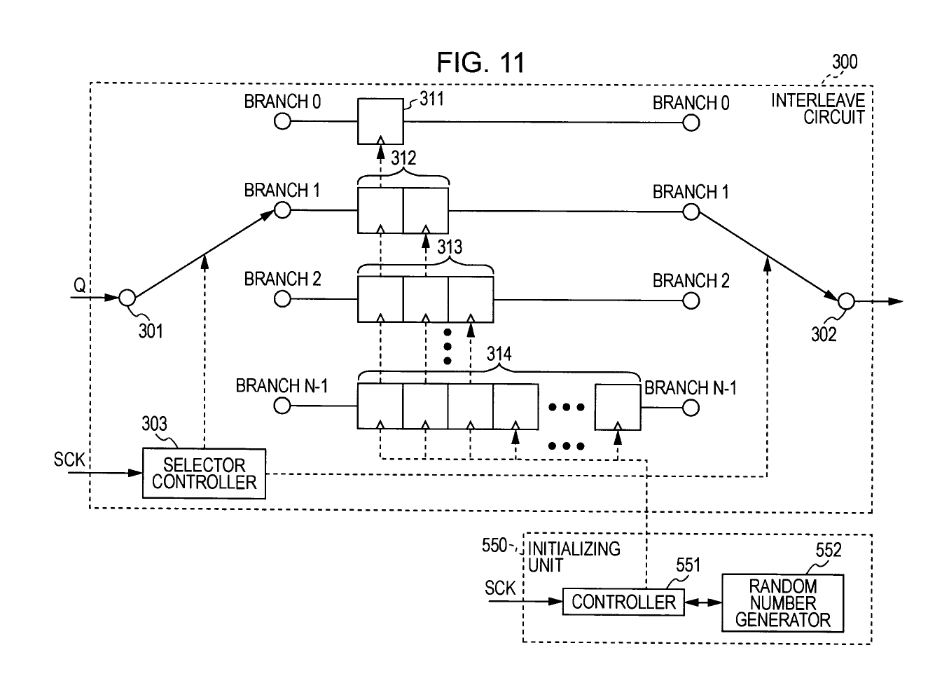

A specific configuration example of the interleave circuit 300 and the initializing unit 550 is illustrated in FIG. 11. The initializing unit 550 includes a controller 551 and a random number generator 552. The controller 551 performs initialization control of the registers in the interleave circuit 300, and the random number generator 552 performs a process of generating a set value for initializing the registers in the interleave circuit 300, the set value being a random number.

The controller 551 switches input of the registers in the interleave circuit 300 to input from the random number generator 552, and causes all the registers to be initialized at one time with a random number when a clock pulse is applied to the SCK.

The random number generator 552 generates a random number sequence that is necessary for initializing the registers in the interleave circuit 300. That is, when the interleave circuit 300 includes registers for Z bits, the random number generator 552 generates a Z-bit random number sequence, which is supplied to each of the registers at initialization of the registers.

Hereinafter, a specific example of values of the individual registers initialized with a random number sequence will be described.

A description will be given about a case where the number of branches N in the interleave circuit 300 is 4. When the number of branches N=4, the number of stages of registers in the interleave circuit 300 is 1+2+3+4 =10.

The random number generator 552 generates a random number sequence {r0, r1, r2, . . . , r9} corresponding to ten register set values.

The individual registers are initialized with those values. In this case, the value of the register 311 is {r0}, the value of the register 312 is {r2, r1}, the value of the register 313 is {r5, r4, r3}, and the value of the register 314 is {r9, r8, r7, r6}, for example.

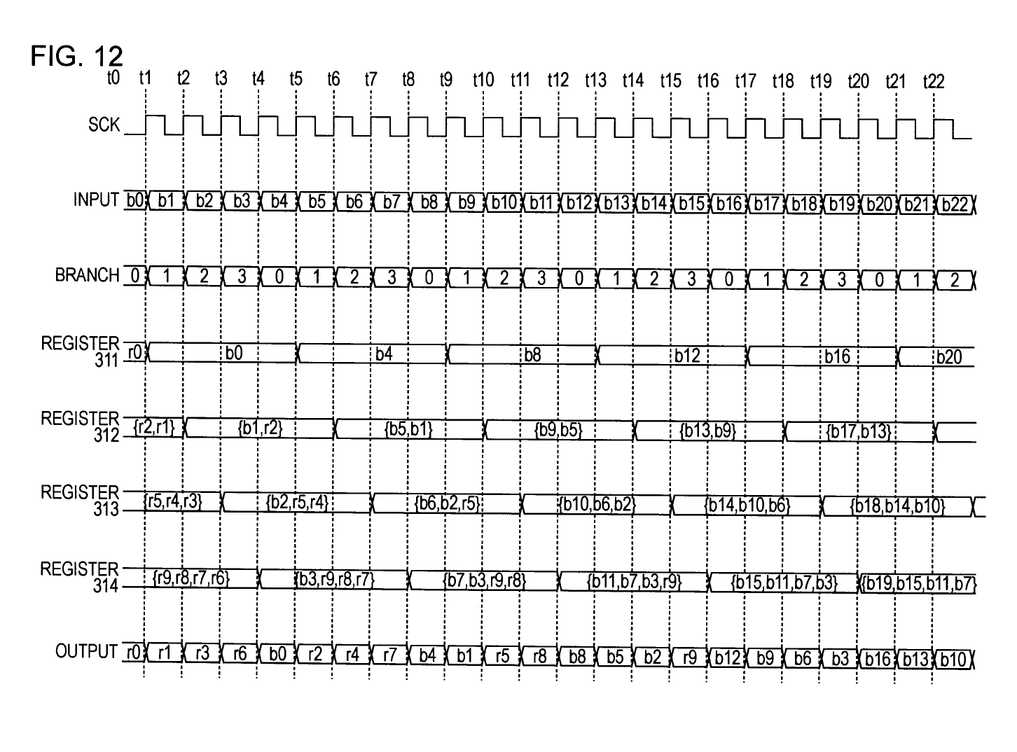

FIG. 12 is a timing chart in a case where the registers are initialized with the foregoing random numbers in the first embodiment. The signals are similar to those described above with reference to FIG. 5.

At time t0, the individual registers are initialized and the foregoing random numbers are stored in the registers. At time t1 and thereafter, the values stored in the scan FFs connected by the scan chain are stored in the registers in the interleave circuit 300. The bit sequence input to the interleave circuit 300 is {b0, b1, b2, b3, b4, . . . }, which is similar to the input bit sequence in the description of operation in the first embodiment. The operation is similar to that in the first embodiment, and thus a detailed description about the operation is omitted.

As can be understood from the timing chart illustrated in FIG. 12, an input bit sequence and an output bit sequence of the interleave circuit 300 have the following setting.

An input bit sequence {b0, b1, b2, b3, b4, . . . } is processed by the interleave circuit 300, thereby becoming {r0, r1, r3, r6, b0, r2, r4, r7, b4, b1, r5, r8, . . . }.

The scanned-out bit sequence of the first embodiment illustrated in FIG. 5 includes an initialized value, that is, 0. However, in the third embodiment, random numbers are output in portions where 0 is output in the first embodiment. Accordingly, the following effect can be obtained.

As described above in the first embodiment, in a case where the individual registers in the interleave circuit are initialized with a fixed value, the number of branches N of the interleave circuit can be estimated on the basis of the number of sequential fixed values (0 in the first embodiment) output from the start of a scan test, so that the effect of bit diffusion performed by the interleave circuit can be negated. However, with the application of the third embodiment, fixed values that are sequentially output are replaced by random numbers. Therefore, it is difficult to estimate the number of branches from a bit sequence output through scan-out, and it is necessary for an attacker to search for all candidates of the number of branches, as described above in each embodiment.

On the other hand, a manufacturer capable of duly performing a scan test can perform a normal scan test by preparing an inverse function of the interleave circuit and converting a scanned-out bit sequence into a bit sequence before input to the interleave circuit. That is, even when an initializing function is added, a new operation is unnecessary for a bit sequence scanned out by the function.

An example of initialization of the registers in the interleave circuit is described in the third embodiment. Other than this example, any configuration having a function of initializing the individual registers in the interleave circuit to values unknown to an attacker at each time may be used.

A configuration example in which the initializing unit is added to the first embodiment has been described. Alternatively, the initializing unit may be combined with the second embodiment. The addition of the initializing unit can increase difficulty in analyzing secret information.

As briefly described above, the configuration of the interleave circuit 300 is not limited to a combination of selectors and registers, and other circuit configurations may also be employed as long as the data diffusion function can be realized. For example, a computation circuit for performing a data conversion process and an encrypting circuit may be applied to the circuit configuration. Additionally, in terms of preventing leakage of secret information, it is effective to lay out a scan chain so that registers for storing secret information such as key information are connected discretely, not sequentially. That is, for example, by setting a scan chain in which a plurality of registers for storing secret information such as an encryption key are connected discretely, not sequentially, the difficulty in analyzing data from an output through the scan chain can be further increased.

In the above-described embodiments, descriptions have been given mainly about a configuration of an integrated circuit. Alternatively, the semiconductor integrated circuit described above in the embodiments may be loaded in an information processing apparatus, such as a personal computer (PC), and control may be performed on a data diffusion process in the semiconductor integrated circuit according to each of the above-described embodiments in the information processing apparatus. The control of the process can be executed by the controller in the semiconductor integrated circuit described above in the embodiments by using a program stored in a memory in the semiconductor integrated circuit. Alternatively, control may be performed on a data diffusion process, such as an interleave process, by inputting a command into the semiconductor integrated circuit having the above-described configuration by executing a program with the use of a controller and a memory provided in an LSI element connected to the semiconductor integrated circuit in the information processing apparatus.

Detailed descriptions about the specific embodiments of the present invention have been given above. However, it is obvious that those skilled in the art can achieve modifications or substitutes of the embodiments without deviating from the scope of the present invention. That is, the embodiments of the present invention have been disclosed in the form of examples, and should not be interpreted in a limited manner. The attached claims should be considered to determine the scope of the present invention.

The series of processes described in this specification can be executed using either of hardware and software, or a composite configuration of hardware and software. In a case where the processes are executed using software, a program describing a processing sequence can be executed by being installed into a memory of a computer incorporated into dedicated hardware, or the program can be executed by being installed into a multi-purpose computer capable of executing various processes. For example, the program can be recorded in advance in a recording medium. Instead of being installed from a recording medium into a computer, the program can be received via a network, such as a local area network (LAN) or the Internet, and can be installed into a recording medium, such as an internal hard disk.

The various processes described in the specification may be executed in parallel or individually in accordance with the processing ability of an apparatus that executes the processes or according to necessity, in addition to be executed in time series in accordance with the description. In this specification, a system means a logical set of a plurality of apparatuses, and the apparatuses having respective configurations are not necessarily in the same casing.

The present application contains subject matter related to that disclosed in Japanese Priority Patent Application JP 2009-111748 filed in the Japan Patent Office on May 1, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor integrated circuit comprising:
a scan chain configured to serve as a connection path used for testing the semiconductor integrated circuit and connect a plurality of flip-flops; and
an interleave circuit provided at an output portion of the scan chain,
wherein the interleave circuit includes
a plurality of branches including different numbers of stages of storage elements,
a selector configured to select one of the plurality of branches serving as an input/output branch that performs input of data from the scan chain and output of data from the interleave circuit, and
a selector controller configured to execute a process of switching among the plurality of branches to select the input/output branch at every predetermined timing.

2. The semiconductor integrated circuit according to claim 1,
wherein the selector controller executes a process of switching among the plurality of branches to select the input/output branch every time data is input from the scan chain.

3. The semiconductor integrated circuit according to claim 1,
wherein the selector controller executes a process of switching among the plurality of branches in accordance with a preset switching sequence.

4. The semiconductor integrated circuit according to claim 1, further comprising:
a memory configured to store a branch selection table used for selecting one of the plurality of branches serving as the input/output branch that performs input of data from the scan chain and output of data from the interleave circuit, memory addresses and branch identifiers being associated with each other in the branch selection table;
a counter configured to count a count value at every predetermined timing; and
a control circuit including a controller configured to output, from the branch selection table, a branch identifier corresponding to a memory address corresponding to a count value of the counter to the selector controller of the interleave circuit,
wherein the selector controller executes a process of selecting a branch corresponding to the branch identifier input from the control circuit as the input/output branch.

5. The semiconductor integrated circuit according to claim 4,
wherein the branch selection table has a setting in which the branch identifiers are randomly associated with the memory addresses, and
wherein the selector controller executes a process of randomly selecting the input/output branch in accordance with branch identifiers in a random sequence input from the control circuit.

6. The semiconductor integrated circuit according to any of claims 1 to 5, further comprising:
an initializing unit configured to set initial values of the storage elements included in the plurality of branches.

7. The semiconductor integrated circuit according to claim 6,
wherein the initializing unit includes a random number generator and executes an initialization process of inputting random numbers generated by the random number generator as initial values of the storage elements included in the plurality of branches.

8. The semiconductor integrated circuit according to any of claims 1 to 7,
wherein the storage elements are registers.

9. An information processing apparatus including the semiconductor integrated circuit according to any of claims 1 to 8.

10. An output data diffusion method that is executed in an information processing apparatus, the method comprising the step of:
executing, in an interleave circuit, a process of diffusing an output from a scan chain configured to serve as a connection path used for testing a semiconductor integrated circuit and connect a plurality of flip-flops,
wherein the step of executing includes sequentially switching among a plurality of branches including different numbers of stages of storage elements to select one of the plurality of branches serving as an input/output branch that performs input of data from the scan chain and output of data from the interleave circuit.

11. A program causing an information processing apparatus to execute an output data diffusion process, the program comprising the step of:
executing, in an interleave circuit, a process of diffusing an output from a scan chain configured to serve as a connection path used for testing a semiconductor integrated circuit and connect a plurality of flip-flops,
wherein the step of executing includes sequentially switching among a plurality of branches including different numbers of stages of storage elements to select one of the plurality of branches serving as an input/output branch that performs input of data from the scan chain and output of data from the interleave circuit.
